(19) United States
(12) Patent Application Publication
(10) Pub. No.: US 2010/0148888 A1
(43) Pub. Date: Jun. 17, 2010

(54) FILTER, DUPLEXER AND COMMUNICATION APPARATUS

(75) Inventors: Motoaki HARA, Kawasaki (JP); Tokihiro NISHIHARA, Kawasaki (JP); Shinji TANIGUCHI, Kawasaki (JP); Takeshi SAKASHITA, Kawasaki (JP); Tsuyoshi YOKOYAMA, Kawasaki (JP); Masafumi IWAKI, Kawasaki (JP); Masanori UEDA, Kawasaki (JP); Yasuyuki SAITOU, Yokohama (JP)

Correspondence Address: ARENT FOX LLP, 1050 CONNECTICUT AVENUE, N.W., SUITE 400, WASHINGTON, DC, 20036, US

(73) Assignees: FUJITSU LIMITED, Kawasaki (JP); FUJITSU MEDIA DEVICES LIMITED, Yokohama (JP)

(21) Appl. No.: 12/712,066

(22) Filed: Feb. 24, 2010

Related U.S. Application Data
(63) Continuation of application No. PCT/JP2007/072552, filed on Nov. 21, 2007.

(51) Int. Cl. H03H 9/58; H03H 9/70

(52) U.S. Cl. 333/133; 333/189

(57) ABSTRACT

The filter includes a series arm piezoelectric thin film resonator placed in the series arm and a parallel arm piezoelectric thin film resonator placed in the parallel arm. Each of the series arm piezoelectric thin film resonator and the parallel arm piezoelectric thin film resonator includes a substrate (21), a lower electrode (22) placed on the substrate (21), a piezoelectric film (23) placed on the lower electrode (22) and a upper electrode (24) placed on the piezoelectric film (23). The ratio of the major axis length A to the minor axis length B of the resonant portion (29) in the series arm piezoelectric thin film resonator is larger than that in the parallel arm piezoelectric thin film resonator.

### CROSS-REFERENCE TO RELATED APPLICATION

This application is based upon and claims the benefit of priority of the prior PCT/JP2007/072552, filed on Nov. 21, 2007, the entire contents of which are incorporated herein by reference.

### FIELD

The present application relates to a filter, a duplexer and a communication apparatus.

### BACKGROUND

Due to a rapid proliferation of wireless devices represented by mobile phones, demands for small and lightweight resonators and filters formed by combining these resonators have been increasing. In many cases, wireless devices were mostly equipped with dielectric filters and surface acoustic wave (SAW) filters. Recently, however, they have been often equipped with piezoelectric thin film resonators. Piezoelectric thin film resonators have an excellent high frequency characteristic, as well as they can be reduced in size and can be provided monolithically.

Examples of piezoelectric thin film resonators include an FBAR (Film Bulk Acoustic Resonator) and a SMR (Solidly Mounted Resonator). An FBAR includes a substrate, a lower electrode, a piezoelectric film and an upper electrode. The lower electrode, the piezoelectric film and the upper electrode are laminated on the substrate. A cavity is formed below the lower electrode at a portion where the lower electrode and the upper electrode oppose each other through the piezoelectric film (resonant portion). Japanese Laid-open Patent Publication No. S60-189307 discloses that a cavity is formed between the lower electrode and the substrate by wet etching a sacrificial layer provided on the surface of the substrate. A known document discloses that a via hole is formed in the substrate by wet etching or dry etching. The known document is K. NAKAMURA, H. SASAKI, H. SHIMIZU, “ZnO/SiO₂-DIAPHRAGM COMPOSITE RESONATOR ON A SILICON WAFER” Electron. Lett., 1981, Vol. 17, pp. 507 to 509. An SMR is provided with an acoustic multilayer film. The acoustic multilayer film is a film that has a film thickness of λ/4 (λ: wavelength of acoustic wave) formed by laminating films having a high acoustic impedance and films having a low acoustic impedance in alternate order.

In the filters, piezoelectric thin film resonators are respectively placed in the series arm and the parallel arm that are connected between the input terminal and the output terminal. The filters operate as band-pass filters when the resonant frequency of the piezoelectric thin film resonator in the series arm and the antiresonant frequency of the piezoelectric resonator in the parallel arm substantially coincide with each other.

As wireless devices have become smaller in size and the amount of power consumed by them has become smaller in recent years, there are demands for filters having low loss in the pass band.

### SUMMARY

The filter of the present application includes a series arm piezoelectric thin film resonator placed in a series arm and a parallel arm piezoelectric thin film resonator placed in a parallel arm. Each of the series arm piezoelectric thin film resonator and the parallel arm piezoelectric thin film resonator includes a substrate, a lower electrode placed on the substrate, a piezoelectric film placed on the lower substrate and a upper electrode placed on the piezoelectric film. The lower electrode and the upper electrode between which the piezoelectric film is interposed oppose each other to form a resonant portion. In order to solve the above-mentioned problem, the ratio of the largest width A to the smallest width B (A/B) of the resonant portion in a plane direction of the piezoelectric film in the series arm piezoelectric film resonator is larger than that in the parallel arm piezoelectric film resonator.

The object and advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF DRAWINGS

FIG. 1 is a circuit diagram illustrating a ladder-type filter according to Embodiment 1.

FIG. 2A is a plan view illustrating a series resonator according to Embodiment 1.

FIG. 2B is a cross-sectional view illustrating the series resonator according to Embodiment 1.

FIG. 2C is a cross-sectional view illustrating a parallel resonator according to Embodiment 1.

FIG. 3A is a circuit diagram illustrating the series arm of the ladder-type filter according to Embodiment 1.

FIG. 3B is a circuit diagram illustrating the parallel arm of the ladder-type filter according to Embodiment 1.

FIG. 3C is a graph illustrating the attenuation characteristic of each of the series arm and the parallel arm of the ladder-type filter according to Embodiment 1.

FIG. 4A is a circuit diagram illustrating one of the stages of the ladder-type filter according to Embodiment 1.

FIG. 4B is a graph illustrating the attenuation characteristic of the stage of the ladder-type filter according to Embodiment 1.

FIG. 5A is a graph illustrating the Q value at the resonant point relative to the axial ratio of the piezoelectric thin film resonator according to Embodiment 1.

FIG. 5B is a graph illustrating the Q value at the antiresonant point relative to the axial ratio of the piezoelectric thin film resonator according to Embodiment 1.

FIG. 6A is a cross-sectional view illustrating a step of manufacturing the ladder-type filter according to Embodiment 1.

FIG. 6B is a cross-sectional view illustrating a step of manufacturing the ladder-type filter according to Embodiment 1.

FIG. 6C is a cross-sectional view illustrating a step of manufacturing the ladder-type filter according to Embodiment 1.

FIG. 6D is a cross-sectional view illustrating a step of manufacturing the ladder-type filter according to Embodiment 1.

FIG. 7 is a circuit diagram illustrating a ladder-type filter according to one example.

FIG. 8 is a graph illustrating the attenuation characteristic of the ladder-type filter of one example and that of a ladder-type filter of a comparative example.

FIG. 9 is a block diagram illustrating a configuration of a communication apparatus according to Embodiment 2.

### DESCRIPTION OF EMBODIMENTS

The filter includes a series arm piezoelectric thin film resonator placed in a series arm and a parallel arm piezoelectric thin film resonator placed in a parallel arm. Each of the series arm piezoelectric thin film resonator and the parallel arm piezoelectric thin film resonator includes a substrate, a lower electrode placed on the substrate, a piezoelectric film placed on the lower substrate and a upper electrode placed on the piezoelectric film. The lower electrode and the upper electrode between which the piezoelectric film is interposed oppose each other to form a resonant portion. In order to solve the above-mentioned problem, the ratio of the largest width A to the smallest width B (A/B) of the resonant portion in a plane direction of the piezoelectric film in the series arm piezoelectric film resonator is larger than that in the parallel arm piezoelectric film resonator.

In the filter, the shape of the resonant portion may be elliptic or rectangular. By forming the resonant portion particularly in an elliptic shape, it is possible to reduce the occurrence of unnecessary waves in a direction perpendicular to the direction that connects the upper electrode and the lower electrode. By reducing the occurrence of unnecessary waves, it is possible to reduce spurious.

In the filter, a via hole or cavity may be formed in the substrate at a portion below the resonant portion. By configuring the film in this way, it is possible to prevent vibrations in the resonant portion from escaping to the substrate. As a result, it is possible to reduce losses in the filter.

In the filter, the piezoelectric film may be made of aluminum nitride or zinc oxide orientated in the (002) direction. Since aluminum nitride and zinc oxide orientated in the (002) direction have a large piezoelectric effect, losses in the filter become small when the piezoelectric film is made of either of the substances.

The duplexer includes a transmission filter and a reception filter having pass-band frequencies different from those of the transmission filter. At least one of the transmission filter and the reception filter is the above-mentioned filter. Since losses in the filter are small, losses in the duplexer become also small due to this configuration.

### Embodiment 1

### 1. Configuration of Filter

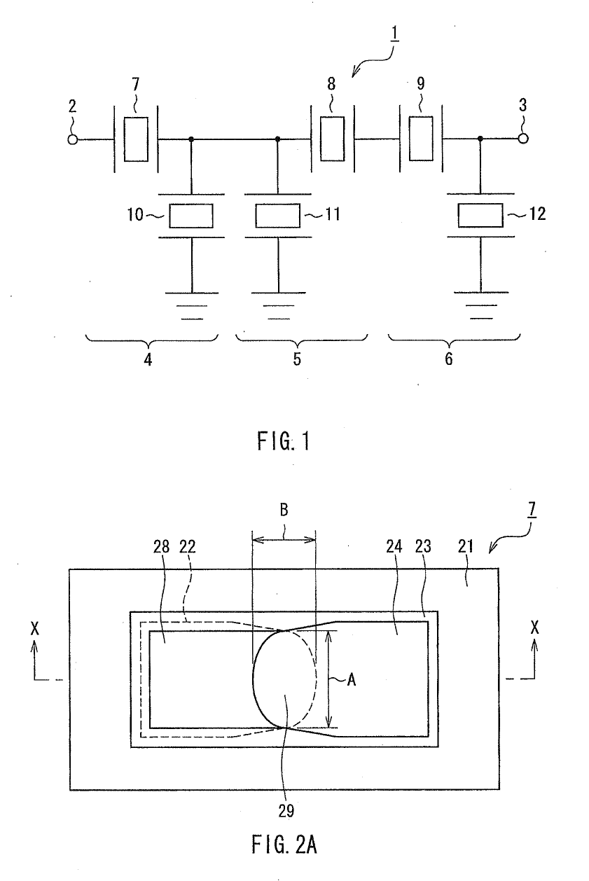

FIG. 1 is a circuit diagram illustrating a ladder-type filter 1 according to Embodiment 1. A first filter 4, a second filter 5 and a third filter 6 are placed between an input terminal 2 and an output terminal 3. The first filter 4 includes a series resonator 7 placed in the series arm and a parallel resonator 10 placed in the parallel arm. The second filter 5 includes a series resonator 8 placed in the series arm and a parallel resonator 11 placed in the parallel arm. The third filter 6 includes a series resonator 9 placed in the series arm and a parallel resonator 12 placed in the parallel arm. The series resonators 7, 8 and 9 and the parallel resonators 10, 11 and 12 are piezoelectric thin film resonators.

The series resonators 7, 8 and 9 resonate on the basis of a resonant frequency Frs and an antiresonant frequency Fas. The parallel resonators 10, 11 and 12 resonate on the basis of a resonant frequency Frp and an antiresonant frequency Fap. The ladder-type filter 1 operates as a pass band filter as a result of the resonant frequency Frs of the series resonators 7, 8 and 9 and the antiresonant frequency Fap of the parallel resonators 10, 11 and 12 substantially coinciding with each other.

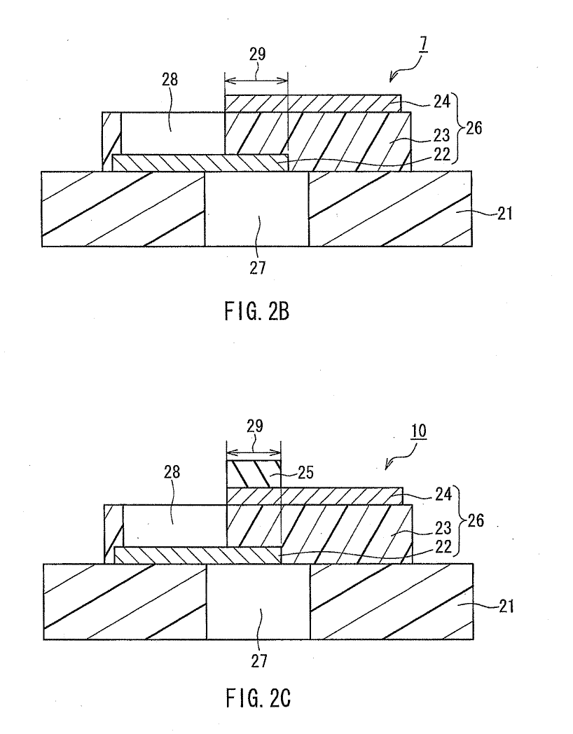

FIG. 2A is a top view illustrating a configuration of the series resonator 7. FIG. 2B is a cross-sectional view taken along the line X-X in FIG. 2A. Note that a configuration of each of the series resonators 8 and 9 is similar to the configuration of the series resonator 7. FIG. 2C is a cross-sectional view illustrating the parallel resonator 10. Note that a configuration of each of the parallel resonators 11 and 12 is similar to the configuration of the parallel resonator 10.

As illustrated in FIGS. 2A and 2B, the series resonator 7 includes a substrate 21, a lower electrode 22, a piezoelectric film 23 and a upper electrode 24. The substrate 21 is made of silicon. In addition to silicon, the substrate 21 may be made of glass, GaAs and the like. The lower electrode 22 is formed on the substrate 21. The piezoelectric film 23 is formed on the substrate 21 and on the lower electrode 22. Aluminum nitride (AlN), zinc oxide (ZnO), lead zirconate titanate (PZT), lead titanate (PbTiO₃) and the like may be used for forming the piezoelectric film 23. An upper electrode 24 is formed on the piezoelectric film 23. Aluminum (Al), copper (Cu), molybdenum (Mo), tungsten (W), tantalum (Ta), platinum (Pt), ruthenium (Ru), rhodium (Rh), iridium (Ir), chrome (Cr), titan (Ti) or a laminate material obtained by combining these substances may be used for forming the lower substrate 22 and the upper substrate 24.

A laminate film 26 includes the lower electrode 22, the piezoelectric film 23 and the upper electrode 24. As illustrated in FIG. 2A, the portion where the lower electrode 22 and the upper electrode 24 oppose each other through the piezoelectric film 23 (resonant portion 29) has an elliptic shape. As illustrated in FIG. 2B, a via hole 27 is formed in the substrate 21 at a portion below the resonant portion 29. Because of this configuration, vibrations in the piezoelectric film 23 do not escape to the substrate 21, so that losses of input and output signals can be prevented. Note that the portion where the via hole 27 is formed is not limited only to the area directly below the resonant portion 29. So long as the via hole 27 is formed in an area that includes the area directly below the resonant portion 29, the effect similar to the present embodiment can be achieved. An opening 28 is formed in the piezoelectric film 23 in the area other than the resonant portion 29. The opening 28 is used for connecting the lower electrode 22 and an external electrode.

When a high-frequency electric signal is applied to the lower electrode 22 and the upper electrode 24, acoustic waves excited by an inverse piezoelectric effect or acoustic waves generated by a distortion resulting from a piezoelectric effect develop in the piezoelectric film 23 that is interposed between the lower electrode 22 and the upper electrode 24. These acoustic waves are converted to electric signals. Since these acoustic waves are totally reflected on the surfaces of the lower electrode 22 and the upper electrode 24 in contact with air, they become longitudinal vibration waves having main displacement in the thickness direction. These acoustic waves resonate when the total film thickness H of the laminate film 26 is N times (“N” is an integer) of the ½ of a wavelength λ. Assuming that the propagation rate of the acoustic waves determined by the material of the piezoelectric film is “V” and the resonant frequency is “F”, they have the following relationship:

V=Fλ.

Thus, the resonant frequency F has the following relationship:

F=N·V/(2H).

Accordingly, by defining the total film thickness H of the laminate film, it is possible to allow the piezoelectric thin film resonator to have a desired frequency characteristic.

As shown in FIG. 2C, the configuration of the parallel resonator 10 is different from that of the series resonator 7 in that a mass-loading film 25 is formed on the upper electrode 24 and the resonant portion 29 has a different shape. The mass-loading film 25 is included in the laminate film 26. The thickness of the mass-loading film 25 is defined such that the resonant frequency and the antiresonant frequency of the parallel resonator 10 become Frp and Fap, respectively.

As shown in FIG. 2A, “A” and “B” denote the elliptic major axis length and the elliptic minor axis length of the resonant portion 29, respectively, and “a:b” denotes the axial ratio of the major axis length A to the minor axis length B (A/B). In each of the series resonators 7, 8 and 9, the axial ratio is larger than that in each of the parallel resonators 10, 11 and 12.

According to the above-mentioned filter, it is possible to reduce losses in the pass band.

### 2. Mechanism for Reducing Losses

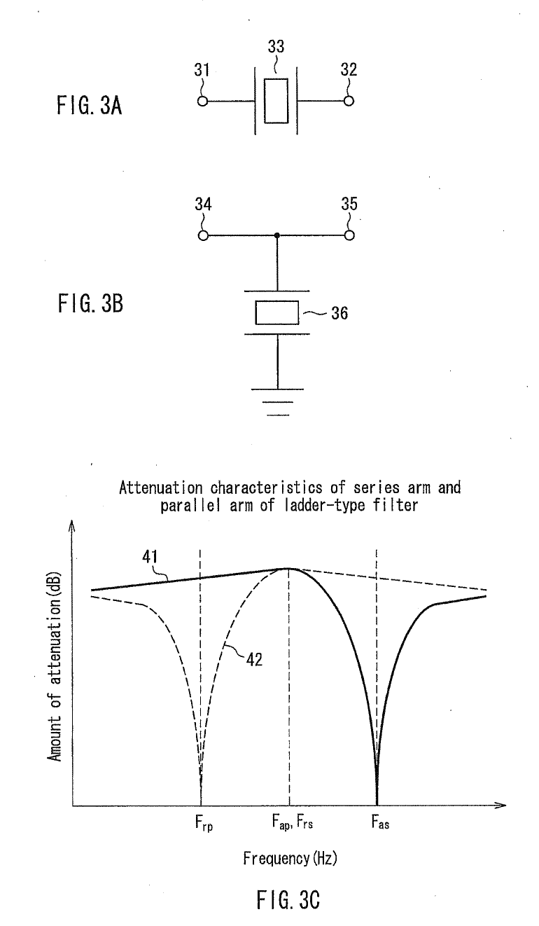

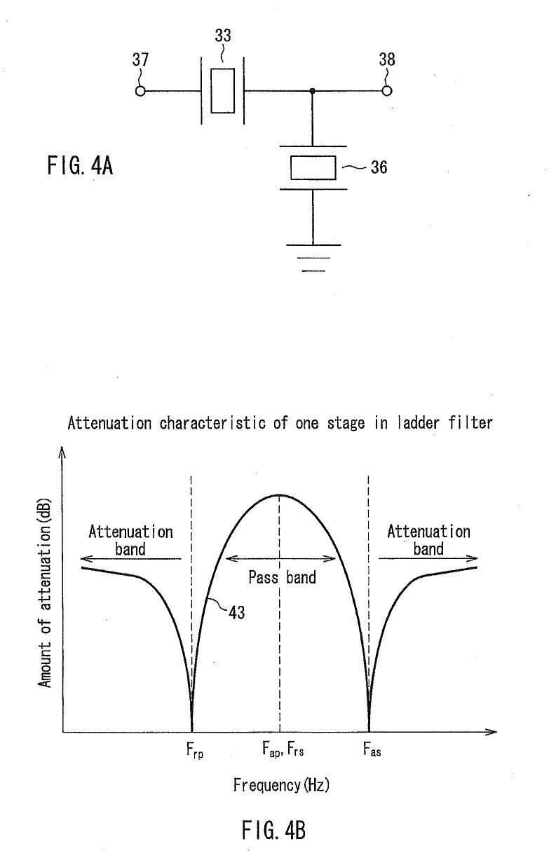

FIG. 3A illustrates a configuration of a series arm in which a series resonator is placed. FIG. 3B is a circuit diagram illustrating a configuration of a parallel arm in which a parallel resonator is placed. FIG. 3C is a graph illustrating frequency characteristics (attenuation characteristics) 41 and 42 of an amount of attenuation in the circuits illustrated in FIGS. 3A and 3B, respectively. FIG. 4A is a circuit diagram illustrating a configuration of a single-stage filter. FIG. 4B is a graph illustrating an attenuation characteristic 43 of the single-stage filter.

The resonant frequency and the antiresonant frequency of a series resonator 33 that is illustrated in FIG. 3A are Frs and Fas, respectively. As the solid line in FIG. 3C indicates, between an input terminal 31 and an output terminal 32, the attenuation characteristic 41 becomes the smallest at the resonant frequency Frs and becomes the largest at the antiresonant frequency Fas. In contrast, the resonant frequency and the antiresonant frequency of a parallel resonator 36 that is illustrated in FIG. 3B are Frp and Fap, respectively. As the dashed line in FIG. 3C indicates, between an input terminal 34 and an output terminal 35, the attenuation characteristic 42 becomes the largest at the resonant frequency Frp and becomes the smallest at the antiresonant frequency Fap.

As illustrated in FIG. 4A, in the filter, the series resonator 33 and the parallel resonator 36 are connected to each other. The resonant frequency Frs of the series resonator 33 and the antiresonant frequency Fap of the parallel resonator 36 substantially coincide with each other. As illustrated in FIG. 4B, between an input terminal 37 and an output terminal 38, the attenuation characteristic 43 becomes like a characteristic that is based on a value obtained by multiplying the value included in the attenuation characteristic 41 and the value included in the attenuation characteristic 42. In other words, with regard to the attenuation characteristic 43, the amount of attenuation is small at frequencies close to the frequency Frs (pass band) and is large (maximum) at the frequencies Frp and Fas. Further, at frequencies lower than the frequency Frp and at frequencies higher than the frequency Fas (attenuation band), the amount of attenuation becomes larger than that in the pass band.

With regard to the attenuation characteristic 43, in order to reduce the amount of attenuation in the pass band, the amount of attenuation of the attenuation characteristic 41 at the frequency Frs and the amount of attenuation of the attenuation characteristic 42 at the frequency Fap could be reduced. In other words, the Q value of each of the series resonators 7, 8 and 9 at the resonant frequency Frs and the Q value of each of the parallel resonators 10, 11 and 12 at the antiresonant frequency Fap could be increased.

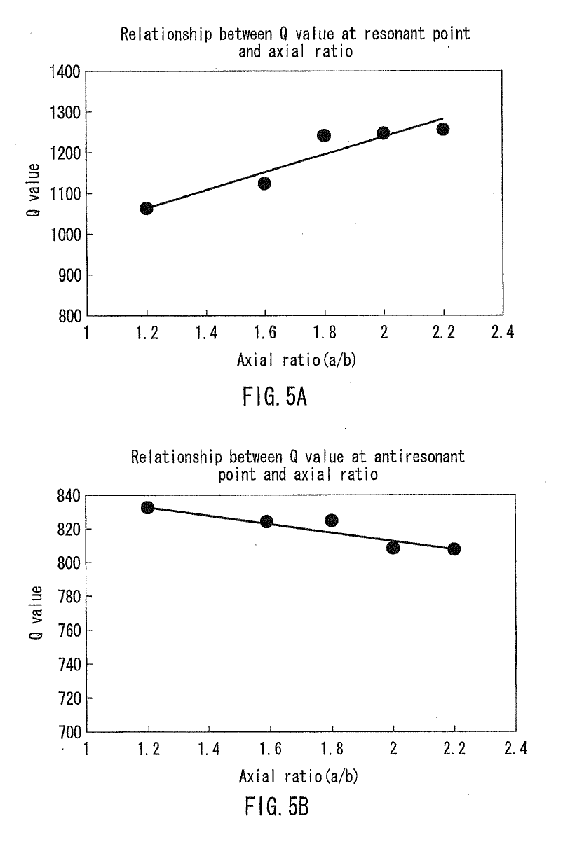

FIG. 5A is a graph providing the results of measuring a change in Q value at the resonant point while changing the axial ratio of the resonant portion. FIG. 5B is a graph providing the results of measuring a change in Q value at the antiresonant point while changing the axial ratio of the resonant portion. Note that “the axial ratio of the resonant portion” refers to a ratio of the major axis to the minor axis of the elliptic resonance portion 29. In the piezoelectric thin film resonator used in the measurement, only the axial ratio is changed while keeping the area of the resonant portion 29 constant so as to match the impedances.

As illustrated in FIG. 5A, the Q value at the resonant point increases as the axial ratio is increased. In contrast, as illustrated in FIG. 5B, the Q value at the antiresonant point decreases as the axial ratio is increased. That is, in order to reduce input and output losses in the filter pass band, the axial ratio of the resonant portion in each of the series resonators 7, 8 and 9 could be increased, and the axial ratio of the resonant portion in each of the parallel resonators 10, 11 and 12 could be reduced.

In the resonant portion 29, when the ratio of the major axis to the minor axis (hereinafter referred to as “axial ratio”) is increased while the size of the area is kept certain, the diameter in the minor axis direction becomes small. When a lead from the upper electrode is placed in the minor axis direction, the length of the lead is reduced, and thereby the resistance loss of the resonator is reduced. This is one of the causes that increase the Q value at the resonant frequency.

The laminate film 26 has a stress at the time of formation. Thus, when the via hole 27 is formed, the laminate film 26 deforms due to the stress. As a result of the laminate film 26 deforming after the formation of the via hole 27, the stress developed at the time of forming the laminate film 26 is released. When the axial ratio of the resonance portion 29 is reduced, the length of the circumference relative to the area of the resonant portion 29 becomes small, thereby facilitating the release of the stress developed at the time of forming the laminate film 26. This is one of the causes that increase the Q value at the antiresonant frequency.

### 3. Method of Manufacturing Filter

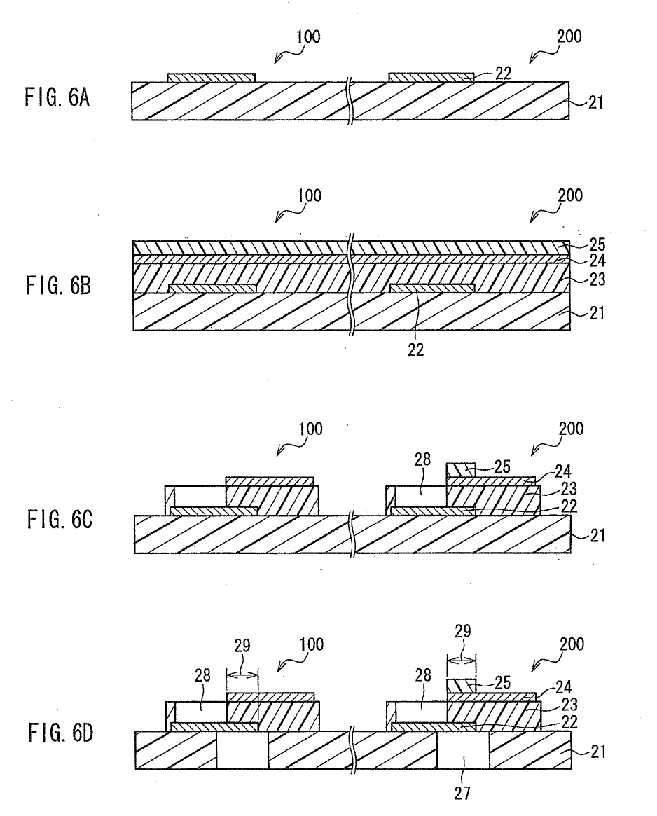

FIGS. 6A to 6D are cross-sectional views each illustrating a step of manufacturing the filter. As illustrated in FIGS. 6A to 6D, a parallel resonator 100 and a series resonator 200 are formed on the same substrate.

First, as illustrated in FIG. 6A, an Ru film is formed on the substrate 21 by sputtering in an atmosphere of Ar gas under a pressure of 0.6 to 1.2 Pa. The substrate 21 is made of silicon. Next, by using exposure and etching techniques, the Ru film (lower electrode 22) is formed so as to form the resonant portion in an elliptic shape.

Then, as illustrated in FIG. 3B, an AIN film (piezoelectric film 23) is formed on the substrate 21 as well as the lower substrate 22 by sputtering in an atmosphere of mixed gas of Ar/N₂ under a pressure of about 0.3 Pa. Subsequently, an Ru film (upper electrode 24) is formed on the piezoelectric film 23 by sputtering in an atmosphere of Ar gas under a pressure of 0.6 to 1.2 Pa. Furthermore, a Ti film (mass-loading film 25) is formed on the upper electrode 24 of the parallel resonator 100 by sputtering.

Next, as illustrated in FIG. 6C, by using exposure and etching techniques, unnecessary parts are removed from the piezoelectric film 23, the upper electrode 24 and the mass-loading film 25 in a predetermined shape. At the same time, the opening 28 is formed in the piezoelectric film 23.

Then, as illustrated in FIG. 6D, by etching the substrate 21 from the backside using Deep-RIE (reactive dry etching), the via hole 27 is formed in the substrate 21 at a portion below the resonant portion 29. Finally, the lower electrode 22 and the upper electrode 24 are connected to other resonators, a ground or signal lines (not shown). Through the above steps, the ladder-type filter 1 is completed.

### 4. Example

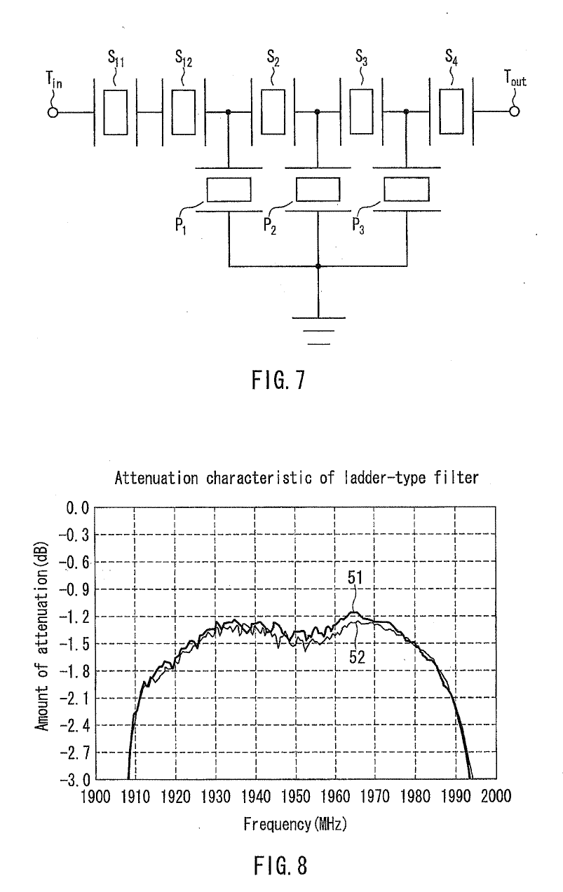

FIG. 7 is a circuit diagram illustrating a ladder-type filter according to the present example. Resonators S11, S12, S2, S3 and S4 are connected in series between an input terminal Tin and an output terminal Tout. A parallel resonator P1 is connected between a node and a ground between the series resonator S12 and the series resonator S2. A parallel resonator P2 is connected between a node and a ground between the series resonator S2 and the series resonator S3. A parallel resonator P3 is connected between a node and a ground between the series resonator S3 and the series resonator S4.

FIG. 8 is a graph illustrating an attenuation characteristic 51 of the ladder-type filer according to the present example and an attenuation characteristic 52 of a ladder-type filter according to a comparative example. The circuit configuration of the filter of the comparative example is similar to that illustrated in the circuit diagram of FIG. 7. In the filter of the present example, the axial ratio of the resonance portion in each series resonator is larger than that in each parallel resonator. In the filter of the comparative example, the axial ratio of the resonance portion in each series resonator and that in each parallel resonator are substantially the same. Table 1 provides the size of each of the series resonators and the parallel resonator included in the filter of the present example. Table 2 provides the size of each of the series resonators and the parallel resonator included in the filter of the comparative example.

TABLE 1

| | | Major axis | Minor axis |
|---|---|---|---|
| | Axial ratio | length | length |
| | a:b | (μm) | (μm) |
| S11 | 9:5 | 268.5 | 149.2 |
| S12 | 8.75:5 | 264.7 | 151.3 |
| S2 | 8.5:5 | 202.2 | 119.0 |
| S3 | 8.25:5 | 183.0 | 116.0 |
| S4 | 8:5 | 252.2 | 157.6 |
| P1 | 6:5 | 191.6 | 159.6 |
| P2 | 6:5 | 177.0 | 147.4 |
| P3 | 6:5 | 172.6 | 143.8 |

TABLE 2

| | | Major axis | Minor axis |
|---|---|---|---|
| | Axial ratio | length | length |
| | a:b | (μm) | (μm) |
| S11 | 6:5 | 219.2 | 182.6 |
| S12 | 6.5:5 | 228.2 | 175.6 |
| S2 | 6:5 | 170.0 | 141.6 |
| S3 | 6:5 | 163.2 | 136.0 |
| S4 | 6:5 | 218.4 | 182.0 |
| P1 | 6:5 | 191.6 | 159.6 |
| P2 | 6:5 | 177.0 | 147.4 |
| P3 | 6:5 | 172.6 | 143.8 |

As for the ladder-type filter of the present example, the axial ratio in each of the parallel resonators P1, P2 and P3 is “6:5”. Further, the axial ratio in the series resonators S11, S12, S2, S3 and S4 is “8.5 to 9:5”, which is larger than the axial ratio in all of the parallel resonators P1, P2 and P3. As for the ladder-type filter of the comparative example in contrast, the axial ratio in each of the parallel resonators P1, P2 and P3 and that in each of the series resonators S11, S12, S2, S3 and S4 are both “6:5” (only the axial ratio in the series resonator S12 is “6.5:5).

As illustrated in FIG. 8, with regard to the attenuation characteristic 51 of the ladder-type filter according to the present example, losses in the pass band (e.g., 1920 to 1980 MHz) are reduced by approximately 0.1 dB in comparison with the attenuation characteristic 52 of the ladder-type filter according to the comparative example. In this way, losses in the pass band become smaller in the ladder-type filter of the present example than in the ladder-type filter of the comparative example.

### 5. Effects of Embodiment, Etc.

In the filter according to the present embodiment, by setting the axial ratio of the resonant portion in the series resonator to be larger than that in the parallel resonator, losses in the pass band can be reduced.

Note that the piezoelectric film 23 is preferably made of aluminum nitride or zinc oxide oriented in the (002) direction. By configuring in this way, it is possible to improve the piezoelectric conversion properties. Consequently, it is possible to further reduce losses in the filter pass band.

Further, an elliptic shape has been adopted for the shape of the resonant portion in the present embodiment, the shape is not limited to elliptic and may be rectangular or the like. The resonance portion at least needs to have a shape having a plurality of widths. By configuring in this way, it is possible to achieve the effect of reducing losses in the pass band. However, it is preferable that the shape of the resonant portion is elliptic because unnecessary waves are less likely to develop in a direction perpendicular to the direction that connects the upper electrode and the lower electrode, and thereby the occurrence of spurious is reduced.

The filter may be a multimode filter, a lattice filter or other type of filter. Further, although the case in which FBARs having via holes are used as the resonators has been described, a similar effect can also be achieved by FBARs having cavities. Further, the resonators are not limited to FBARs and an effect similar to that achieved by the FBARs can also be achieved by SMRs.

### Embodiment 2

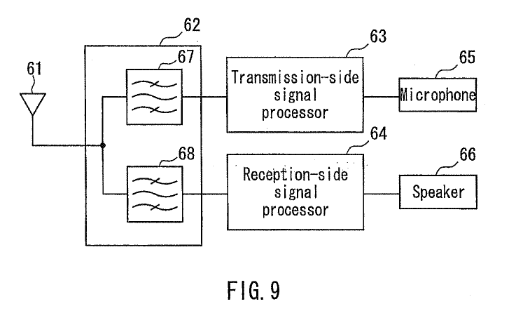

FIG. 9 is a block diagram illustrating a configuration of a communication apparatus according to Embodiment 2. The communication apparatus includes an antenna 61, a duplexer 62, a transmission-side signal processor 63, a reception-side signal processor 64, a microphone 65 and a speaker 66. The duplexer 62 includes a transmission filter 67 and a reception filter 68. The pass band (reception band) of the reception filter 68 is different from that of the transmission filter 67.

The microphone 65 converts a voice to a voice signal and sends the voice signal to the transmission-side signal processor 63. The transmission-side signal processor 63 generates a transmission signal by modulating the voice signal. The duplexer 62 sends the transmission signal generated by the transmission-side signal processor 63 to the antenna 61.

The antenna 61 converts the transmission signal to a radio wave and outputs the radio wave. Further, the antenna 61 converts a radio wave to a reception signal as an electric signal and sends the reception signal to the duplexer 62. The reception filter 68 sends a reception signal in the reception band to the reception-side signal processor 64. On the other hand, since the pass band of the transmission filter 67 is different from the reception band, the transmission filter 67 does not allow the reception signal to pass through. Thus, the reception signal is not inputted to the transmission-side signal processor 63. The reception-side signal processor 64 subjects the reception signal to processing such as detection and amplification, and generates a voice signal. The speaker 66 converts the voice signal to a voice and outputs the voice.

The ladder-type filter 1 illustrated in FIG. 1 is used for each of the transmission filter 67 and the reception filter 68. By configuring in this way, it is possible to reduce losses in each pass band of the transmission filter 67 and the reception filter 68. By using the duplexer 62 including the transmission filter 67 and the reception filter 68, it is possible to reduce power losses of the communication apparatus. As a result, since a radio wave having the same strength as that outputted by a conventional communication apparatus can be outputted using less power than the conventional apparatus, it is possible to increase the usable time of the communication apparatus that is equipped with a battery.

Although the communication apparatus illustrated in FIG. 9 includes the microphone 65 and the speaker 66, it is also applicable to an apparatus not including the microphone 65 or the speaker 66.

Since losses in the pass band are small in the filter of the present application, the filter can be used in a communication apparatus and the like.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

1. A filter comprising:
a series arm piezoelectric thin film resonator placed in a series arm; and
a parallel arm piezoelectric thin film resonator placed in a parallel arm,
wherein each of the series arm piezoelectric thin film resonator and the parallel arm piezoelectric thin film resonator includes a substrate, a lower electrode placed on the substrate, a piezoelectric film placed on the lower electrode and a upper electrode placed on the piezoelectric film, the lower electrode and the upper electrode between which the piezoelectric film is interposed oppose each other to form a resonant portion,
a ratio of the largest width A to the smallest width B (A/B) of the resonant portion in a plane direction of the piezoelectric film in the series arm piezoelectric film resonator is larger than that in the parallel arm piezoelectric film resonator.

2. The filter according to claim 1, wherein the shape of the resonant portion is elliptic or rectangular.

3. The filter according to claim 1, wherein a via hole or cavity is formed in the substrate at a portion below the resonant portion.

4. The filter according to claim 1, wherein the piezoelectric film is made of aluminum nitride or zinc oxide orientated in the (002) direction.

5. A duplexer comprising:
a transmission filter; and
a reception filter having pass-band frequencies different from those of the transmission filter,
wherein at least one of the transmission filter and the reception filter is the filter according to claim 1.
